(19) United States
(12) Patent Application Publication
(10) Pub. No.: US 2026/0180568 A1
(43) Pub. Date: Jun. 25, 2026

(54) MULTI-STAGE PHASE INTERPOLATORS

(71) Applicant: Intel Corporation, Santa Clara, CA (US)

(72) Inventors: Soumya BOSE, Hillsboro, OR (US); Zhaokai LIU, Foster City, CA (US); Mozhgan MANSURI, Portland, OR (US); Susnata MONDAL, Hillsboro, OR (US)

(21) Appl. No.: 18/987,315

(22) Filed: Dec. 19, 2024

(51) Int. Cl. H03K 5/135; G06F 11/07; G11C 7/22; H03K 5/00

(52) U.S. Cl. CPC H03K 5/135; G06F 11/073; G06F 11/0793; G11C 7/222; H03K 2005/00052

(57) ABSTRACT

Multi-stage phase interpolator circuits with single bit coded phase interpolator cells, some of which may include error correction cells and/or edge-triggered cells. The multi-stage interpolator circuits may include adjustable inter-stage capacitors and may be controlled to avoid glitching due to abrupt code transitions.

### TECHNICAL FIELD

Embodiments of the invention relate to the field of semiconductor circuits and more specifically, to the field of phase interpolator circuits.

### BRIEF DESCRIPTION OF THE DRAWINGS

The disclosure may best be understood by referring to the following description and accompanying drawings that are used to illustrate embodiments of the invention. In the drawings:

FIG. 1 is a diagram showing a conventional inverter based quadrature output phase interpolator.

FIGS. 2A and 2B are diagrams showing a multi-stage phase interpolator circuit in accordance with some embodiments.

FIGS. 3A-3D are diagrams illustrating skew issues with conventional 2:1 PI cell circuits.

FIGS. 4A-4E are diagrams illustrating a 2:1 phase interpolator cell circuit with an edge-triggered feature in accordance with some embodiments.

FIG. 5A is a diagram showing a 2:2 bit cell circuit with error correction in accordance with some embodiments.

FIG. 5B shows a 2:2 PI cell with error correction in accordance with some additional embodiments.

FIG. 6A is a diagram showing a multi-stage 4-channel (quarter phase output) 8-bit Phase Interpolator in accordance with some embodiments.

FIG. 6B is a diagram showing a multi-stage PI circuit in accordance with some additional embodiments.

FIG. 6C is a diagram showing yet another embodiment of a multi-stage phase interpolator circuit in accordance with some embodiments.

FIGS. 7A-7F are diagrams showing a coding sequence to reduce glitches for a multi-stage phase interpolator circuit in accordance with some embodiments.

FIG. 8 illustrates an example computing system with one or more phase interpolator circuits as disclosed herein.

FIG. 9 illustrates a block diagram of an example processor and/or SoC that may have one or more cores and clock generation circuits with one or more phase interpolator circuits as disclosed herein.

FIG. 10 is a block diagram illustrating a computing system configured to implement one or more aspects of the phase interpolator circuit examples described herein.

### DETAILED DESCRIPTION

Scalable and power efficient phase interpolator circuits with high resolution and linearity are valuable building blocks in a variety of different circuits including clock/data recovery (CDR), de-skewing and clock generation for high-speed interconnects, phase locked loops (PLLs), and time to digital converters, to mention just a few. A phase interpolator (PI) takes first and second input clock phases and generates an output clock with a phase shifted to a location within the first and second clock phases. Depending on the resolution of the PI, the specific interpolated location is set by a digital code value that places the output phase at a corresponding fraction between the first and second input clock phases.

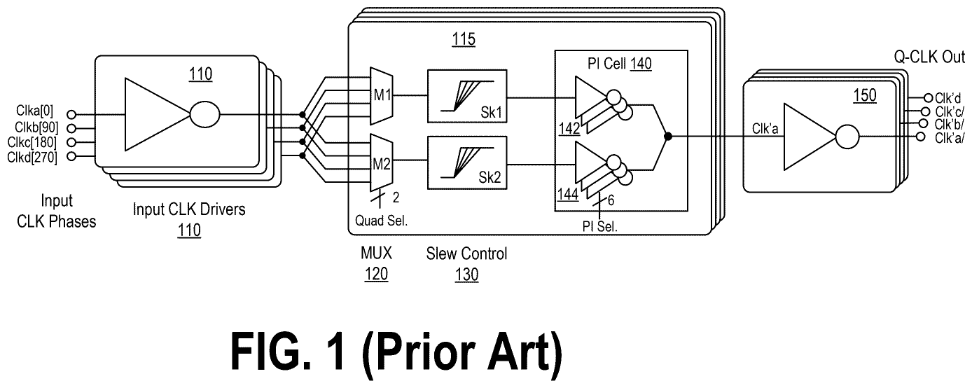

FIG. 1 is a diagram showing a conventional inverter based quadrature output phase interpolator. The circuit has four input drivers 110, four PI circuit blocks (or PI blocks) 115, and four output drivers 150, coupled together as shown. The quadrature (or quad) generator receives, at the input drivers 110, four input clocks (referred hereafter also as clock phases), Clka-Clkd, that are separated by 90 degrees. Multiplexers 120 (M1, M2) in each PI block (115) direct a selected two of the four inputs into an associated one of the four PI blocks. Typically, each PI block receives a different pair of adjacent clock phase inputs (e.g., 0/90, 90/180, etc.). For each PI block, a received clock phase pair is appropriately skewed through slew control circuit 130 and then phase interpolated by an inverter-based PI cell 140. Each PI cell includes a pair of adjustable strength inverters (142, 144) that are coupled together at their outputs. A PI select (PI Sel) code controls the relative strengths of the adjustable inverters relative to each other, causing them to generate an output clock with a selected phase within the inputs that corresponds to the selected code. The adjustable drive-strength inverters (142, 144) typically include a number of switchably engageable, parallel-coupled inverters to control their respective drive strengths.

In this way, each PI block generates an associated interpolated output clock phase. The interpolated outputs are then buffered through associated output drivers 150 to provide output clock phases (Clka/-Clkd/), each separated by 90 degrees from its adjacent clocks but shifted, together, by an amount corresponding to the applied PI select code.

These inverter-based so-called flash PI cells scale well with technology but suffer from non-linearities, especially when interpolating square wave clock phases. Accordingly, they usually need slew control circuits, as depicted in the figure. In addition, to improve the phase shifting resolution, large numbers of adjustable inverters in the PI cells are typically needed, which increases loading to the preceding stages. Moreover, fan-out of the system typically degrades at mid-code settings, requiring more drivers following the PI cells. Any of these issues alone could be problematic, but taken as a whole, an excessive overall amount of power is consumed, and the problem becomes even worse when considering overall clock distribution networks that may use multiple instantiations of such PI circuits.

Accordingly, new PI circuit approaches are desired. In some embodiments, PI designs are provided that mitigate against non-linearities with phase interpolators in a power efficient manner. Some embodiments provide a multi-stage PI architecture with one or several different features for improving overall PI operability. Some of the features include an edge-triggered phase interpolator cell, with common tail transistors, for accurate mid-phase interpolation without having to use slew control for slewing the edges of the input clocks. Another feature provides error correction within a PI cell to reduce residual error in mid-phase interpolation, making designs more robust across process variations. In addition, a variable capacitor calibration feature is provided in some embodiments to reduce errors, especially at most significant bit stages of a PI circuit. With combinations of one or more of these, an/or other features, an N-bit multi-stage PI circuit may be implemented that can achieve good linearity, even for square wave clocks, with reasonable power consumption. For example, with some embodiments, an 8-bit PI circuit was able to achieve a DNL (differential non-linearity) of 0.7 LSB (least significant bits) and an INL (integral non-linearity) of 1.7 LSB at low power (e.g., 7 mW at 8 GHz).

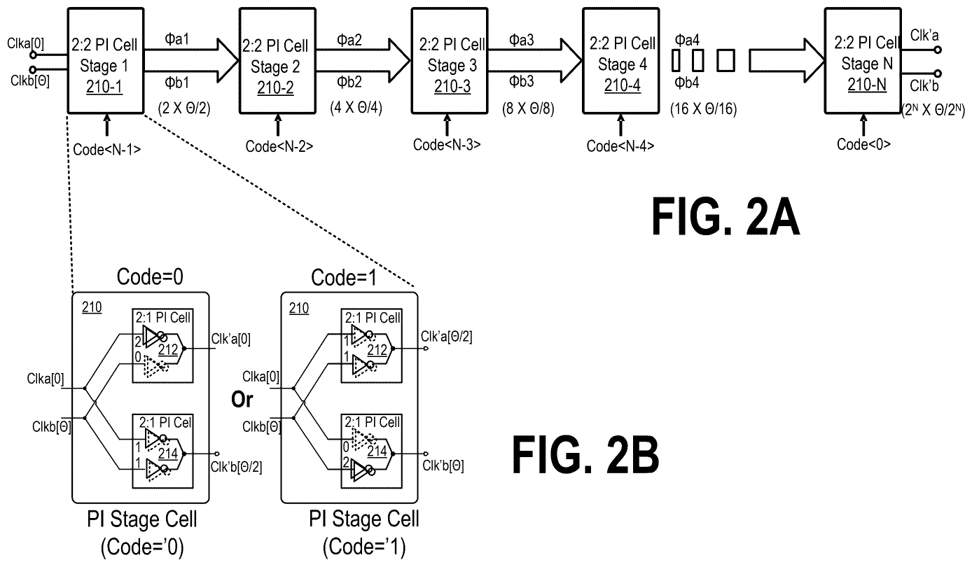

FIGS. 2A and 2B are diagrams showing a multi-stage phase interpolator circuit in accordance with some embodiments. FIG. 2A shows the multi-stage circuit architecture with N stages, while FIG. 2B illustrates an example of a single stage PI cell that may be used for implementing some or all of the stages. FIG. 2B also conceptually shows the PI cell 210 in each of its two possible select code states. The multi-stage architecture allows for fine bit PI resolution, e.g., N bits as shown, without excessive loading for use in a clock generation or distribution system.

The depicted PI circuit comprises N multiple PI cell stages 210 (210-1 through 210-N). Each of these stages are formed from a 2:2 bit cell. This means that it receives two input clock phases and generates two interpolated output clocks with a phase difference that is half of the phase difference of the input clocks. With this example, each of the 2:2 bit cells 210 includes two 2:1 PI cells (212, 214), as is shown in FIG. 2B. The 2:1 bit cells are each formed from a pair of adjustable strength inverters coupled together at their outputs. With the depicted implementation, two switchably controllable parallel coupled inverters are used for each of the adjustable strength inverters. The switches are controlled by an input PI select bit (not shown) that for each 2:1 cell, either turns on one of the inverters in each pair or turns on both inverters in one leg of the pair and turns off both of the inverters in the other leg. This is represented in FIG. 2B.

When the select code is ‘0, both inverters of the upper leg of 2:1 cell 212 are turned on with the inverters in the other leg turned off. Conversely, each of the legs in 2:1 bit cell 214 has one of its inverters turned on and the other turned off. In this way, bit cell 212 passes the Clka input clock, which is at 0 degrees, through to its output (Clk′a) without any notable phase shifting. On the other hand, bit cell 214 phase interpolates its inputs (Clka, Clkb) to generate an output (Clk′b) with a phase of Θ/2 degrees. Accordingly, the 2;2 PI cell 210 generates outputs (Clk′a, Clk′b) having a phase difference that is 1/2 of the input clock's phase difference.

When the select code is ‘1, the 2:2 PI circuit 210 works similarly but in an opposite manner. It still generates an output difference that is ½ of the difference of the input, but the output clocks are each shifted ahead by Θ/2 degrees. PI cell 212 outputs a clock (Clk′a) that is Θ/2, while PI cell 214 outputs a clock (Clk′b) that has a phase of Θ degrees.

Returning back to FIG. 2A, each stage receives first and second input clock phases and generates output clocks with phase differences that are half of their inputs, although the outputs will be shifted or not shifted depending on whether their 2:2 PI cell 210 has a select code of ‘1 or ‘0. That is, functionally, each stage multiplexes one of the input clock phases to its respective output and mid-phase interpolates the input clocks to the other output based on the selected 1-bit code. Each stage equivalently divides the phase sector bounded by the input clock phases and generates the boundary clock phases of one half of the phase sector. The division and selection continue through subsequent stages resulting in the generation of an output clock phase whose phase can be shifted in fine resolution based on the code bits of individual stages. A phase shifting resolution of ½^{N} may thus be achieved by using N number of interpolating stages.

With this multi-stage configuration, A single bit PI stage reduces the loading of the preceding stage and is independent of the total required resolution of the phase interpolation, making it a favorably scalable architecture. Moreover, with the final stage being driven by two closely spaced clock phases, it has enhanced drivability across codes, improving the fan out and power efficiency of clock distribution.

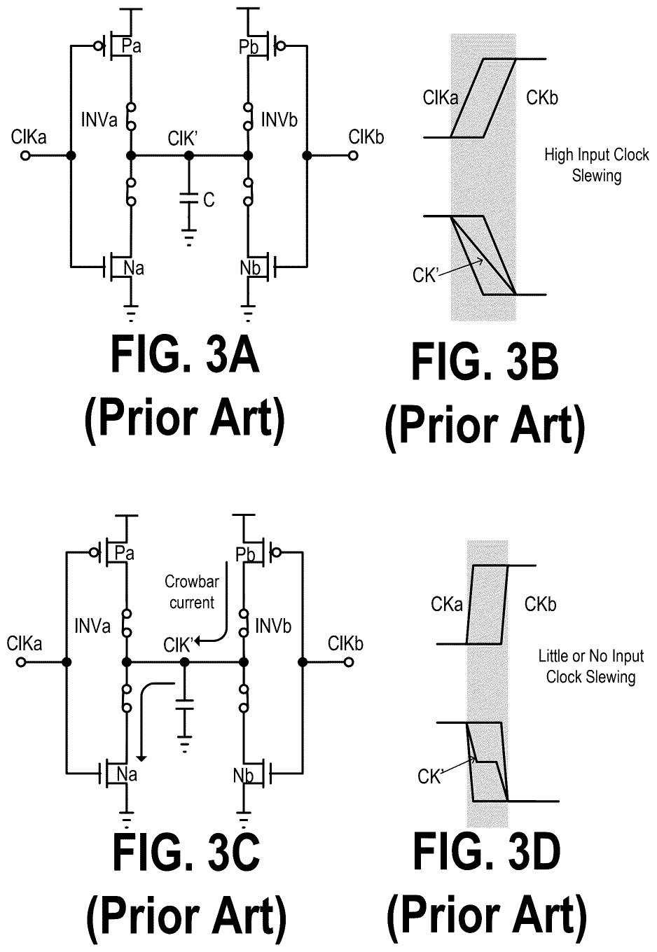

FIGS. 3A-3D are diagrams illustrating skew issues with conventional 2:1 PI cell circuits. FIG. 3A shows a conventional 2:1 PI cell circuit that includes a pair of switchably controllable inverters with their outputs coupled together. The inverters include P-type transistors (Pa, Pb) and N-type transistors (Na, Nb) coupled together as shown. There are also switches (e.g., transistors) for select code implementation and a capacitance (C) at their outputs. This capacitance may be parasitic or may include a separate capacitive element.

As can be seen in the signal diagram of FIG. 3B, when the input clocks have sufficient skew, the interpolated output (Clk′) has a reasonably smooth sloping profile. However, as seen in FIGS. 3C and 3D, when the input clocks do not have sufficient skew, the output is compromised, generating a step glitch at a cross-over between when the leading clock (Clka) goes high and the trailing clock (Clkb) is still low. Without input clock slewing, the non-overlapped edges of the input clocks result in crowbar current flow. Thus, especially with midpoint phase interpolation, when both inverters are equivalently driven, a relatively large error may be encountered.

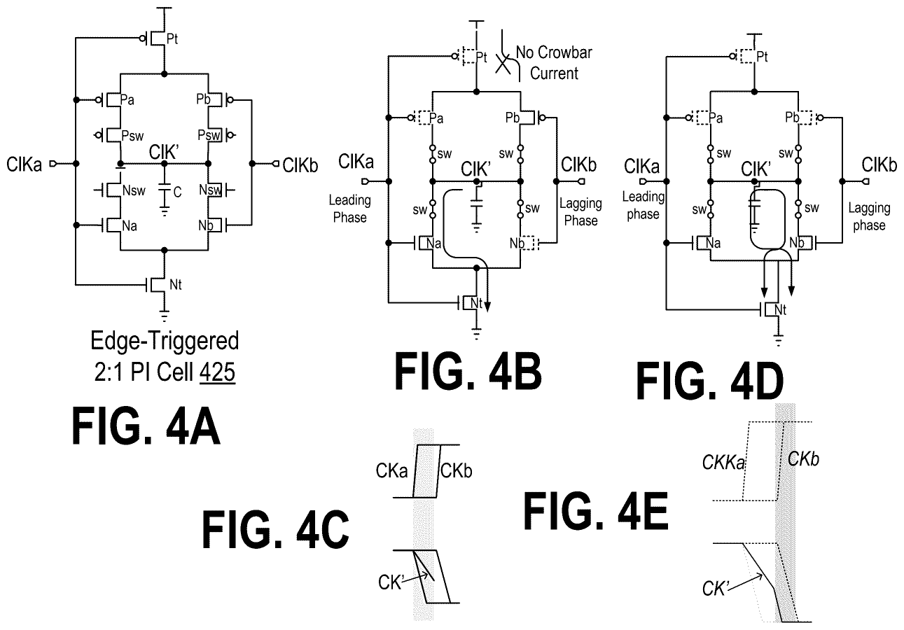

FIGS. 4A-4E are diagrams illustrating a 2:1 phase interpolator cell circuit with an edge-triggered feature in accordance with some embodiments. The edge-trigger feature allows the cell to operate using lower power and at the same time, achieve slew-independent mid-phase interpolation. As shown in FIG. 4A, the circuit is similar to the PI cell of FIG. 3A, but the inverters on the leading clock side are coupled to common tail transistors (Pt, Nt) coupled, respectively, between inverter high supply reference nodes and high supply nodes, on the one end, and coupled between inverter low supply reference nodes and low supply nodes on the other end. The gates of the common tail transistors are coupled to the input of the inverter receiving the leading clock phase.

As shown in FIGS. 4B-4E, this technique disables the pull-up (or pull-down) path based on the leading phase transition. FIGS. 4B, 4C show the circuit when the leading clock is high and the lagging clock is low, and FIGS. 4D, 4E show the circuit when both clocks have risen to a high state. The common tail transistors can stop, or at least inhibit, the crowbar current from flowing in the cycle when the input clocks are at different states (e.g., Clka is high, Clkb is low). By doing this, the interpolation can become independent of the slew of the input clocks and can depend more so on the RC constant of the output path, or output slewing. Proper sizing of the transistors can make the phase of the interpolated clock close to, the middle of the input phases. (It should be noted that with the leading clock phase driving the common tail transistors, there is an asymmetrical loading of the input clock phases for a single 2:1 PI cell, in isolation. If used in this way, it may call for dummy loading stages for the lagging phase side. However, with multi-phase output clock generation, the input phases behave both as leading and lagging phases for each channel, resulting in a symmetrical loading.

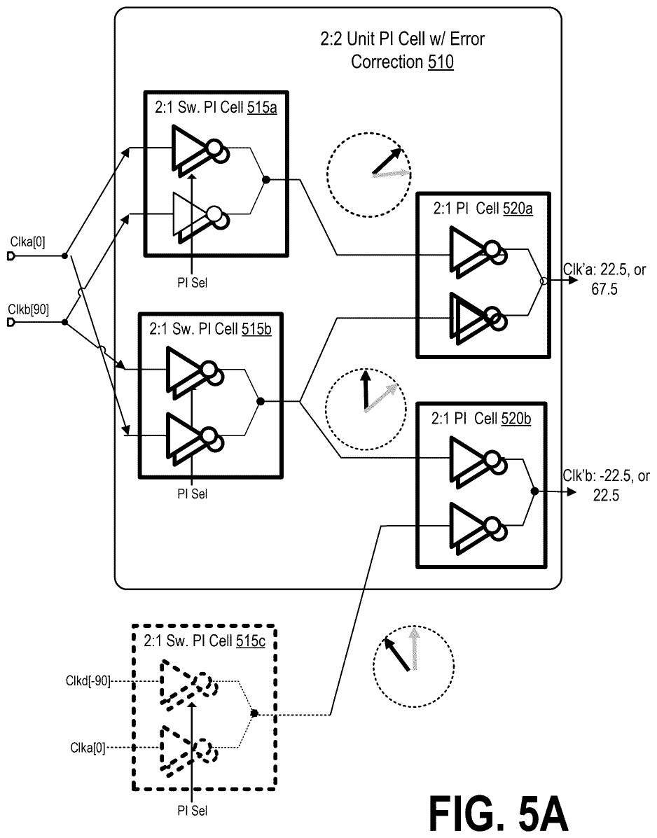

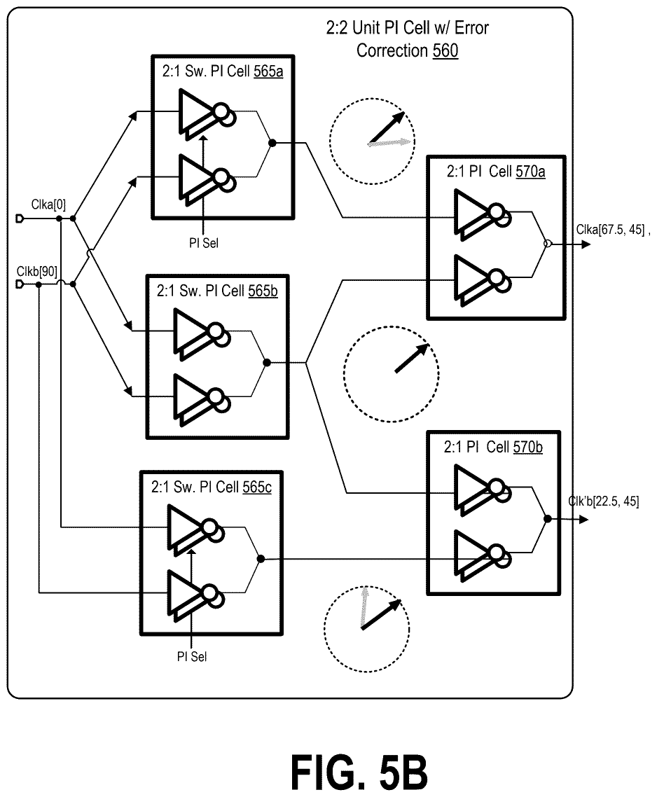

FIG. 5A is a diagram showing a 2:2 bit cell circuit with error correction in accordance with some embodiments. The 2:2 PI cell 510 includes first and second switchable 2:1 PI cells 515a, 515b, along with first and second 2:1 error correction midpoint PI cells 520a, 520b, coupled together as shown. With this implementation, PI cells 515 are referred to as “switchable” since they can be controlled with a select bit to either interpolate their inputs or to pass through their lower input (Clkb[90] for cell 515a and Clka[0] for cell 515b). This is in contrast with the error correction 2:1 cells, which are referred to as error correction “midpoint” cells since they are fixed to perform a midpoint interpolation on their two input clocks.

The first error correction cell 520a receives as one of its inputs the output from the first switchable 2:1 cell 515a. Its other input comes from the output of the second switchable 2:1 PI cell 515b, which is also provided as one of the inputs to the second error correction cell 520b. The other input to the second error correction cell 520b comes from a third switchable 2:1PI cell 515c, which has as its inputs Clka[0] and a Clkd[−90]. This third switchable 2:1 PI cell may come from anywhere, but in some embodiments, its part of a quadrature phase PI generation circuit that outputs four clocks, each 90 degrees apart but shifted based on a select code provided to its four PI circuit blocks. With this example, the depicted 2:2 PI cell with error correction 510 is in a first quadrant with inputs (Clka, Clkb) at 0 and 90 degrees, respectively. The third switchable 2:1 PI cell 515c is from a neighboring fourth quadrant with inputs of 270 degrees (i.e., −90 degrees) and 0 degrees.

The phasor diagrams illustrate first and second states of the first stage (515a-c) outputs based on the applied PI select bit. The dark phasors correspond to a first state, while the gray phasors correspond to a second state. So, for the first state, the first error correction cell 520a performs midpoint interpolation on 45 and 0 degree inputs, generating an output of 22.5 degrees, and the second error correction cell 520b performs midpoint interpolation on 0 and −45 degree inputs, generating an output of −22.5 degrees. So, the overall output is still interpolated by ½, a 90 degree differential input is interpolated to a 45 degree output differential, albeit the actual phases are shifted ahead, by 22.5 degrees. The second state produces similar results with the outputs from error correction cells 520a, 520b being 67.5 and 22.5 degrees, respectively. Again, the differential output is interpolated by ½ to 45 degrees, although this time phase shifted behind by 22.5 degrees. For ease of description, the applied values were used without any errors, but it can be seen that regardless of whether the first or second switchable 2:1 PI cell has an error, e.g., above or below the 45 degree target, the error correction cells nonetheless operate to reduce the overall differential error.

Without the error correction cells, process mismatches of the transistors can lead to deviations of the slope factor in the two phases leading to mid-phase interpolation errors. To address this, the error correction stage cancels out this systematic error by summing up two interpolated clocks from adjacent phase sectors. The error correction stage further interpolates between the non-interpolated and interpolated output clock phases. This results in a delay of each clock phase depending upon the phase separation between adjacent non-interpolated and interpolated clock phases, which compensates for the interpolation error of the previous stage. This also compensates for the process dependent duty-cycle distortion of the output clock phase. In a multi-phase clocking scheme, the error correction stage can utilize clock phases in the adjacent sector (quadrant) and does not require any additional phase generation. FIG. 5B shows another embodiment that does not rely on a PI cell from an adjacent quadrant.

FIG. 5B shows a 2:2 PI cell with error correction in accordance with some additional embodiments. This circuit operates similarly with the circuit of FIG. 5A, but it incorporates the third switchable 2:1 PI c ell (565c) and is not dependent on a cell from an adjacent quadrant. In addition, the second first stage 2:1 cell 565b is not switchable but instead operates as the error correction cells, performing a fixed midpoint interpolation on the inputs. Note also that this 2:2 PI cell with error correction also does not require a separate (third) clock but is self operable, e.g., as a 2:2 PI cell in a multi-stage PI circuit for a single quadrant, 2-input, 2-output PI circuit.

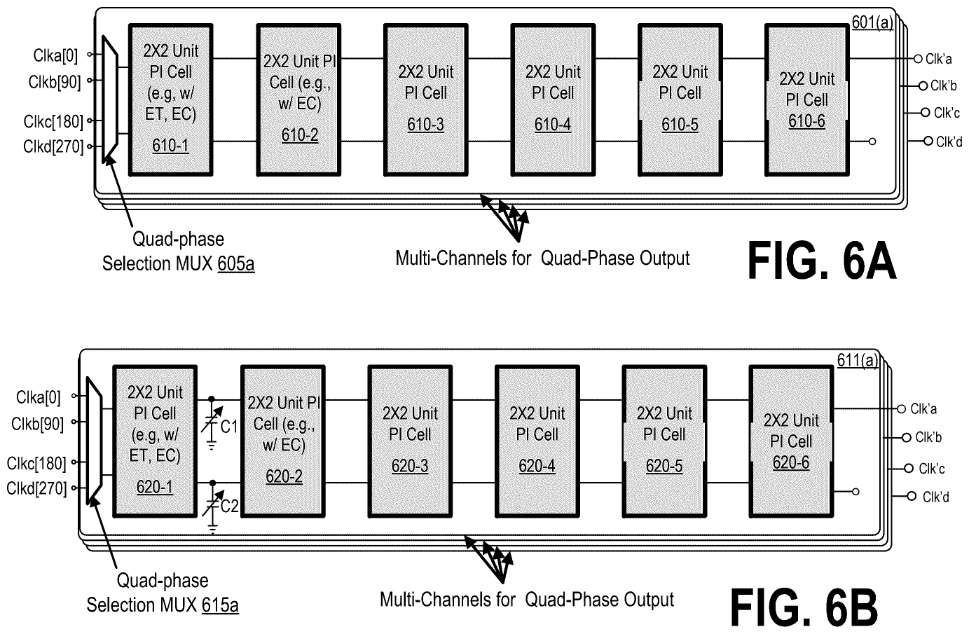

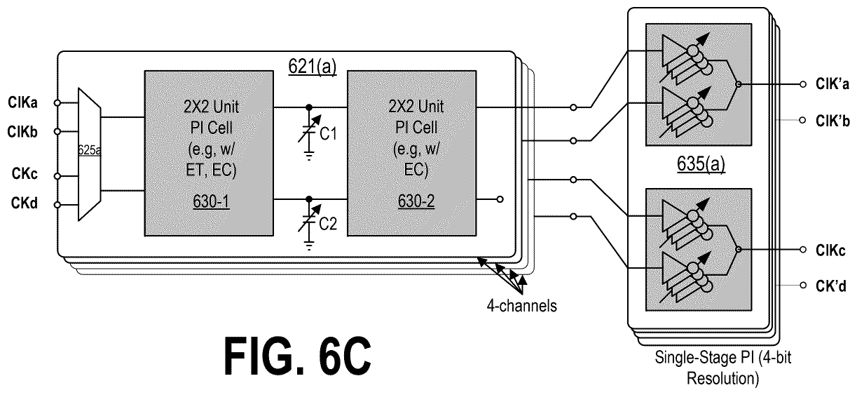

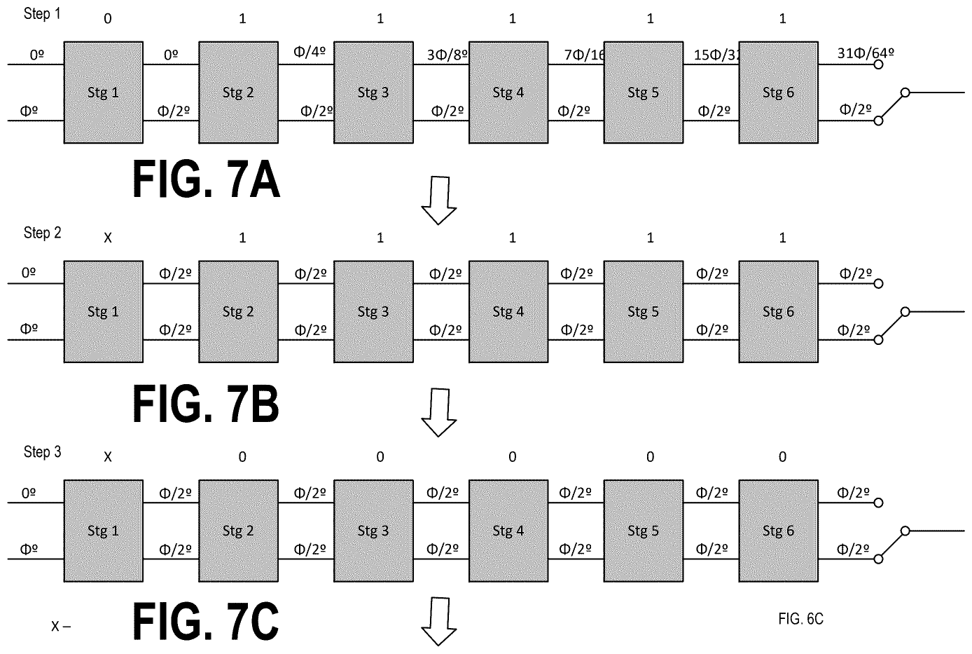

FIG. 6A is a diagram showing a multi-stage 4-channel (quarter phase output) 8-bit Phase Interpolator in accordance with some embodiments. This PI circuit may be used in a variety of applications such as with a 4-channel quarter-rate receiver/transmitter architecture. At the input of the interpolator circuit 601 for each channel there is a 4:2 mux (605) that selects two quarterly phased clock inputs. Each channel generates individual quarter phases of the output clock. Six-stages of interpolation together with the multiplexing of quarter phase clocks gives a total of 8-bit resolution phase shift of the output clock.

This multi-stage PI circuit may utilize one or more of the features discussed herein. For example, as shown in the figure, in some embodiments, the first two stages (610-1, 610-2) comprise 2:2 PI cells with error-correction cell stages included within them. In addition, the first stage (610-1) also uses edge-trigger PI cells for slew rate independency, while conventional 2:1 cells may be used in the subsequent stages. Due to the mid-phase interpolation at each stage, there is no separate requirement of a decoder, and the 6-bit LSB of the PI code can be fed to each stage of interpolation. In some embodiments, the mux select lines are decoded from the 2 most significant bits of the overall PI select code.

An embodiment of this circuit was simulated using an 8 GHz clock and a 0.9 V supply. It performed with a phase linearity with a DNL less than 2 LSB and an INL less than 4 LSB, along with minimal variation across process corners, as a result of the error correction cells in the first two stages. Note that this may be improved even further using adjustable stage input capacitors, e.g., as discussed in the following section. In addition, the output clock showed minimal duty-cycle variation across the PI codes. Total power consumption of the 4-channel PI including the input mux was less than 7 mW and was constant across PI codes due to the reduction in crowbar current. The reduced input loading and improved output fan-out of the PI resulted in more than 2×power reduction in the entire receiver clock distribution path compared to an implementation with a single-stage conventional CMOS flash PI. Note that the PI stages could also be utilized as a part of the clock distribution by increasing the fan-out of each interpolation stages and thereby reducing subsequent clock-distribution power.

FIG. 6B is a diagram showing a multi-stage PI circuit in accordance with some additional embodiments. This implementation may be similar to the circuit of FIG. 6A except that it additionally includes adjustable capacitors for inter-stage phase calibration. In the depicted embodiment, the multi-stage PI circuit includes adjustable capacitors, e.g., formed from controllable/switchably engageable CMOS transistors with their sources and drains coupled together, coupled at the output/input nodes between the first and second 2:2 PI cell stages. The capacitors serve to compensate for errors caused by the first PI stage and the quadrant multiplexer by creating extra delay. Note that the inserted delay can spread into adjacent outputs. Therefore, the calibration locations should be carefully selected to avoid additional delay spreading into adjacent channels. For example, it can also happen at the output of the second 2:2 cell stage. The additional delay effectively stretches out the phases evenly to compensate for the errors.

FIG. 6C is a diagram showing yet another embodiment of a multi-stage phase interpolator circuit in accordance with some embodiments. This circuit is a hybrid combination of pipelined (multi-stage) PI cells (630-1, 630-2) coupled with conventional adjustable drive strength multi-bit (flash PI) PI cells (635).

The multi-stage aspect allows for lower supply voltage. However, at lower supply voltages, the quality of the clock signal, notwithstanding the features discussed herein, can degrade as it propagates through multiple PI stages. Also, the intrinsic delay of the clocks become higher. To enable the desired lower supply voltage operation, the single-bit 2:2 PI cell stages are combined with a conventional multi-bit single-stage CMOS flash PI as shown in the figure. In this scheme, the 4-LSBs control the single-stage flash PI cell, the next 2 code bits are used in the first two single-bit 2:2 PIs, and the 2 MSBs are used to select the clock phases of the input mux. The first two single-bit PI stages improve the linearity compared to a full 6-bit conventional single-stage CMOS PI (FIG. 1).

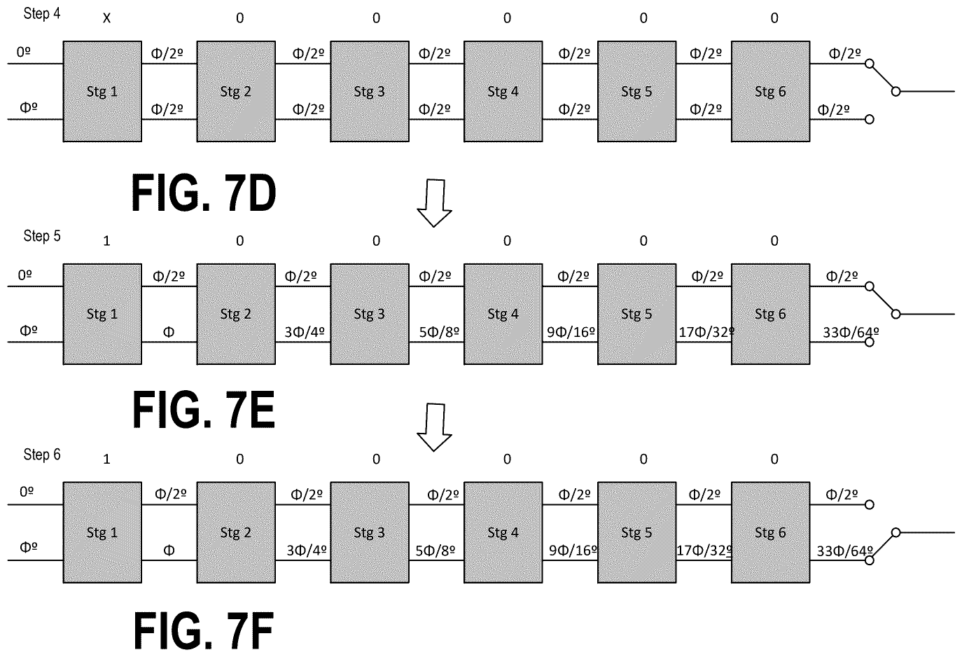

FIGS. 7A-7F are diagrams showing a coding sequence to reduce glitches for a multi-stage phase interpolator circuit in accordance with some embodiments. It has been observed that code word transitions could lead to sudden jumps (or glitches) in phase for a single clock edge (e.g., single multi-stage PI circuit code word change from 011111 to 100000 after the clock propagates through the first stage. So, the effective code word for that clock edge, in the downstream 5 stages for this example, would have suddenly changed from all ‘1s to all ‘0s. Accordingly, in some embodiments, instead of a single jump from one code to the next, a circuitous route is taken that avoids such extreme changes. That is, Intermediate states through the PI decoder may be employed. Note that with this, as well as with the other embodiments disclosed herein, 2:2 PI cells are used that an example sequence is shown with reference to FIGS. 7A-7F.

Here, the MSB, instead of going directly from 0->1 goes through a state X (step 2) when both the outputs of the PI stage are mid-phase interpolated. (With these diagrams, note that “X” represents a state in which both the switchable 2:1 PI cells in a single 2:2 PI cell generate midpoint interpolated outputs. Thus, in some embodiments, one of the two states for each 2:2 cells is a state where both 2:1 PIs are interpolating, with the other state using one of the 2:1 cells to interpolate and the other to pass through one of the two inputs.) This makes all of the outputs of the subsequent stages the same. During this time, while keeping the MSB state as X, flipping the LSBs (as done in step 3) would not impact the output clock since both the outputs are identical.

In the next state (step 4) the output is sampled from the other output of the final stage to make sure that the output clock is unperturbed. Now while the output clock is transferred by this end of the output stage, the MSB is flipped to 1 (step 5) so that the required phase is transferred to the second output of the final stage. Finally, (step 6) the desired output is sampled back to get the desired output clock phase. In some embodiments, these intermediate states can be repeated in some or every MSB flipping and can be taken care of by an FSM (finite state machine) in a decoder.

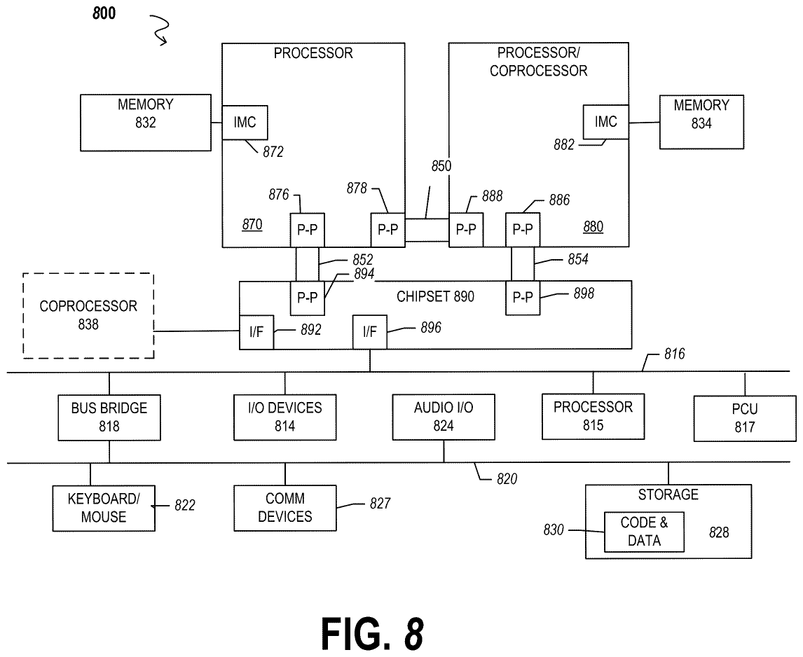

FIG. 8 illustrates an example computing system with one or more phase interpolator circuits as disclosed herein. Multiprocessor system 800 is an interfaced system and includes a plurality of processors including a first processor 870 and a second processor 880 coupled via an interface 850 such as a point-to-point (P-P) interconnect, a fabric, and/or bus. In some examples, the first processor 870 and the second processor 880 are homogeneous. In some examples, first processor 870 and the second processor 880 are heterogenous. Though the example system 800 is shown to have two processors, the system may have three or more processors, or may be a single processor system. In some examples, the computing system is implemented, wholly or partially, with a system on a chip (SoC) or a multi-chip (or multi-chiplet) module, in the same or in different package combinations.

Processors 870 and 880 are shown including integrated memory controller (IMC) circuitry 872 and 882, respectively. Processor 870 also includes interface circuits 876 and 878, along with core sets. Similarly, second processor 880 includes interface circuits 886 and 888, along with a core set as well. A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 870, 880 may exchange information via the interface 850 using interface circuits 878, 888. IMCs 872 and 882 couple the processors 870, 880 to respective memories, namely a memory 832 and a memory 834, which may be portions of main memory locally attached to the respective processors.

Processors 870, 880 may each exchange information with a network interface (NW I/F) 890 via individual interfaces 852, 854 using interface circuits 876, 894, 886, 898. The network interface 890 (e.g., one or more of an interconnect, bus, and/or fabric, and in some examples is a chipset) may optionally exchange information with a coprocessor 838 via an interface circuit 892. In some examples, the coprocessor 838 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 870, 880 or outside of both processors, yet connected with the processors via an interface such as P-P interconnect, such that either or both processors' local cache information may be stored in the shared cache if a processor is placed into a low power mode.

Network interface 890 may be coupled to a first interface 816 via interface circuit 896. In some examples, first interface 816 may be an interface such as a Peripheral Component Interconnect (PCI) interconnect, a PCI Express interconnect, or another I/O interconnect. In some examples, first interface 816 is coupled to a power control unit (PCU) 817, which may include circuitry, software, and/or firmware to perform power management operations with regard to the processors 870, 880 and/or co-processor 838. PCU 817 provides control information to one or more voltage regulators (not shown) to cause the voltage regulator(s) to generate the appropriate regulated voltage(s). PCU 817 also provides control information to control the operating voltage generated. In various examples, PCU 817 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 817 is illustrated as being present as logic separate from the processor 870 and/or processor 880. In other cases, PCU 817 may execute on a given one or more of cores (not shown) of processor 870 or 880. In some cases, PCU 817 may be implemented as a microcontroller (dedicated or general-purpose) or other control logic configured to execute its own dedicated power management code, sometimes referred to as P-code. In yet other examples, power management operations to be performed by PCU 817 may be implemented externally to a processor, such as by way of a separate power management integrated circuit (PMIC) or another component external to the processor. In yet other examples, power management operations to be performed by PCU 817 may be implemented within BIOS or other system software. Along these lines, power management may be performed in concert with other power control units implemented autonomously or semi-autonomously, e.g., as controllers or executing software in cores, clusters, IP blocks and/or in other parts of the overall system.

Various I/O devices 814 may be coupled to first interface 816, along with a bus bridge 818 which couples first interface 816 to a second interface 820. In some examples, one or more additional processor(s) 815, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 816. In some examples, second interface 820 may be a low pin count (LPC) interface. Various devices may be coupled to second interface 820 including, for example, a keyboard and/or mouse 822, communication devices 827 and storage circuitry 828. Storage circuitry 828 may be one or more non-transitory machine-readable storage media as described below, such as a disk drive or other mass storage device which may include instructions/code and data 830 and may implement the storage in some examples. Further, an audio I/O 824 may be coupled to second interface 820. Note that other architectures than the point-to-point architecture described above are possible. For example, instead of the point-to-point architecture, a system such as multiprocessor system 800 may implement a multi-drop interface or other such architecture.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality. Example core architectures are described next, followed by descriptions of example processors and computer architectures.

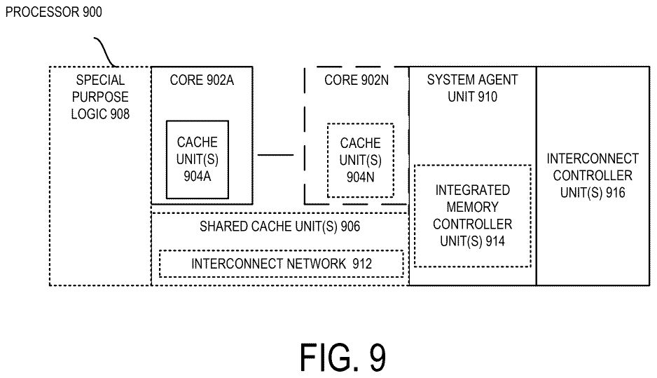

FIG. 9 illustrates a block diagram of an example processor and/or SoC 900 that may have one or more cores and clock generation circuits with one or more phase interpolator circuits as disclosed herein. The solid lined boxes illustrate a processor and/or SoC 900 with a single core 902(A), system agent unit circuitry 910, and a set of one or more interface controller unit(s) circuitry 916, while the optional addition of the dashed lined boxes illustrates an alternative processor and/or SoC 900 with multiple cores 902(A)-(N), a set of one or more integrated memory controller unit(s) circuitry 914 in the system agent unit circuitry 910, and special purpose logic 908, as well as a set of one or more interface controller unit(s) circuitry 916. Note that the processor and/or SoC 900 may be one of the processors 870 or 880, or co-processor 838 or 815 of FIG. 8.

Thus, different implementations of the processor and/or SoC 900 may include: 1) a CPU with the special purpose logic 908 being a high-throughput processor, a network or communication processor, a compression engine, a graphics processor, a general purpose graphics processing unit (GPGPU), a neural-network processing unit (NPU), an embedded processor, a security processor, a matrix accelerator, an in-memory analytics accelerator, a compression accelerator, a data streaming accelerator, data graph operations, or the like (which may include one or more cores, not shown), and the cores 902(A)-(N) being one or more general purpose cores (e.g., general purpose in-order cores, general purpose out-of-order cores, or a combination of the two); 2) a co-processor with the cores 902(A)-(N) being a large number of special purpose cores intended primarily for graphics and/or scientific (throughput); and 3) a co-processor with the cores 902(A)-(N) being a large number of general purpose in-order cores. Thus, the processor and/or SoC 900 may be a general-purpose processor, co-processor or special-purpose processor, such as, for example, a network or communication processor, compression engine, graphics processor, GPGPU (general purpose graphics processing unit), a high throughput many integrated core (MIC) co-processor (including 30 or more cores), embedded processor, or the like. The processor may be implemented on one or more chips. The processor and/or SoC 900 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 904(A)-(N) within the cores 902(A)-(N), a set of one or more shared cache unit(s) circuitry 906, and external memory (not shown) coupled to the set of integrated memory controller unit(s) circuitry 914. The set of one or more shared cache unit(s) circuitry 906 may include one or more mid-level caches, such as level 2 (L2), level 3 (L3), level 4 (L4), or other levels of cache, such as a last level cache (LLC), and/or combinations thereof. While in some examples interface network circuitry 912 (e.g., a ring interconnect) interfaces the special purpose logic 908 (e.g., integrated graphics logic), the set of shared cache unit(s) circuitry 906, and the system agent unit circuitry 910, alternative examples use any number of well-known techniques for interfacing such units. In some examples, coherency is maintained between one or more of the shared cache unit(s) circuitry 906 and cores 902(A)-(N). In some examples, interface controller unit(s) circuitry 916 couple the cores 902(A)-(N) to one or more other devices 918 such as one or more I/O devices, storage, one or more communication devices (e.g., wireless networking, wired networking, etc.), etc.

In some examples, one or more of the cores 902(A)-(N) are capable of multi-threading. The system agent unit circuitry 910 includes those components coordinating and operating cores 902(A)-(N). The system agent unit circuitry 910 may include, for example, power control unit (PCU) circuitry and/or display unit circuitry (not shown). The PCU may be or may include logic and components needed for regulating the power state of the cores 902(A)-(N) and/or the special purpose logic 908 (e.g., integrated graphics logic). The display unit circuitry is for driving one or more externally connected displays.

The cores 902(A)-(N) may be homogenous in terms of instruction set architecture (ISA). Alternatively, the cores 902(A)-(N) may be heterogeneous in terms of ISA; that is, a subset of the cores 902(A)-(N) may be capable of executing an ISA, while other cores may be capable of executing only a subset of that ISA or another ISA.

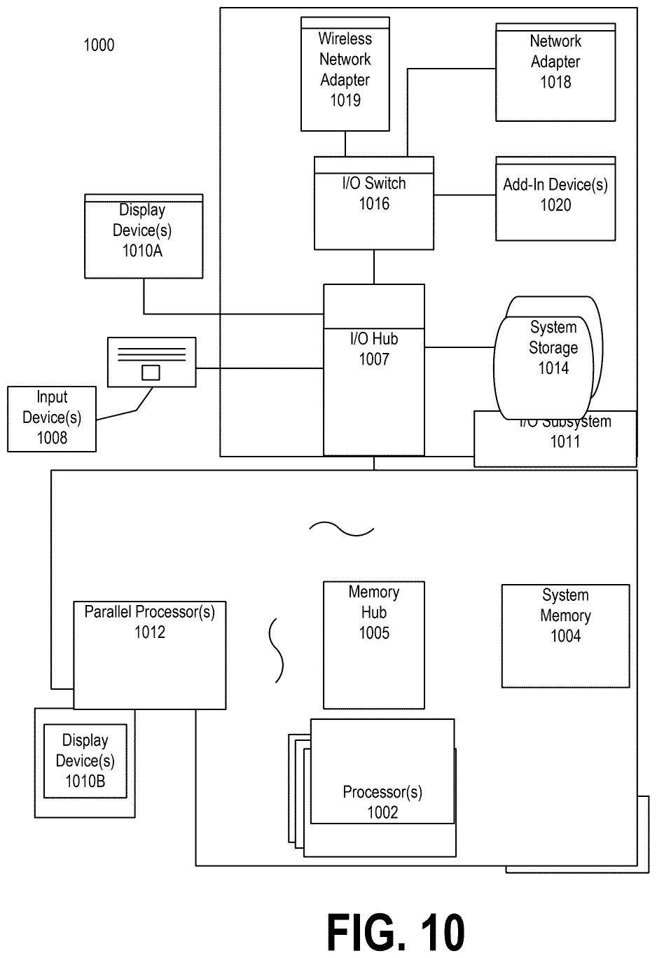

FIG. 10 is a block diagram illustrating a computing system 1000 configured to implement one or more aspects of the examples described herein. The computing system 1000 includes a processing subsystem 1001 having one or more processor(s) 1002 and a system memory 1004 communicating via an interconnection path that may include a memory hub 1005. The memory hub 1005 may be a separate component within a chipset component or may be integrated within the one or more processor(s) 1002. The memory hub 1005 couples with an I/O subsystem 1011 via a communication link 1006. The I/O subsystem 1011 includes an I/O hub 1007 that can enable the computing system 1000 to receive input from one or more input device(s) 1008. Additionally, the I/O hub 1007 can enable a display controller, which may be included in the one or more processor(s) 1002, to provide outputs to one or more display device(s) 1010A. In some examples the one or more display device(s) 1010A coupled with the I/O hub 1007 can include a local, internal, or embedded display device.

The processing subsystem 1001, for example, includes one or more parallel processor(s) 1012 coupled to memory hub 1005 via a bus or communication link 1013. The communication link 1013 may be one of any number of standards-based communication link technologies or protocols, such as, but not limited to PCI Express, or may be a vendor specific communications interface or communications fabric. The one or more parallel processor(s) 1012 may form a computationally focused parallel or vector processing system that can include a large number of processing cores and/or processing clusters, such as a many integrated core (MIC) processor. For example, the one or more parallel processor(s) 1012 form a graphics processing subsystem that can output pixels to one of the one or more display device(s) 1010A coupled via the I/O hub 1007. The one or more parallel processor(s) 1012 can also include a display controller and display interface (not shown) to enable a direct connection to one or more display device(s) 1010B.

Within the I/O subsystem 1011, a system storage unit 1014 can connect to the I/O hub 1007 to provide a storage mechanism for the computing system 1000. An I/O switch 1016 can be used to provide an interface mechanism to enable connections between the I/O hub 1007 and other components, such as a network adapter 1018 and/or wireless network adapter 1019 that may be integrated into the platform, and various other devices that can be added via one or more add-in device(s) 1020. The add-in device(s) 1020 may also include, for example, one or more external graphics processor devices, graphics cards, and/or compute accelerators. The network adapter 1018 can be an Ethernet adapter or another wired network adapter. The wireless network adapter 1019 can include one or more of a Wi-Fi, Bluetooth, near field communication (NFC), or other network device that includes one or more wireless radios.

The computing system 1000 can include other components not explicitly shown, including USB or other port connections, optical storage drives, video capture devices, and the like, which may also be connected to the I/O hub 1007. Communication paths interconnecting the various components in FIG. 10 may be implemented using any suitable protocols, such as PCI (Peripheral Component Interconnect) based protocols (e.g., PCI-Express), or any other bus or point-to-point communication interfaces and/or protocol(s), such as the NVLink high-speed interconnect, Compute Express Link™ (CXL™) (e.g., CXL.mem), Infinity Fabric (IF), Ethernet (IEEE 802.3), remote direct memory access (RDMA), InfiniBand, Internet Wide Area RDMA Protocol (iWARP), Transmission Control Protocol (TCP), User Datagram Protocol (UDP), quick UDP Internet Connections (QUIC), RDMA over Converged Ethernet (RoCE), Intel QuickPath Interconnect (QPI), Intel Ultra Path Interconnect (UPI), Intel On-Chip System Fabric (IOSF), Omnipath, HyperTransport, Advanced Microcontroller Bus Architecture (AMBA) interconnect, OpenCAPI, Gen-Z, Cache Coherent Interconnect for Accelerators (CCIX), 3GPP Long Term Evolution (LTE) (4G), 3GPP 5G, and variations thereof, or wired or wireless interconnect protocols known in the art. In some examples, data can be copied or stored to virtualized storage nodes using a protocol such as non-volatile memory express (NVMe) over Fabrics (NVMe-oF) or NVMe.

The one or more parallel processor(s) 1012 may incorporate circuitry optimized for graphics and video processing, including, for example, video output circuitry, and constitutes a graphics processing unit (GPU). Alternatively or additionally, the one or more parallel processor(s) 1012 can incorporate circuitry optimized for general purpose processing, while preserving the underlying computational architecture, described in greater detail herein. Components of the computing system 1000 may be integrated with one or more other system elements on a single integrated circuit. For example, the one or more parallel processor(s) 1012, memory hub 1005, processor(s) 1002, and I/O hub 1007 can be integrated into a system on chip (SoC) integrated circuit. Alternatively, the components of the computing system 1000 can be integrated into a single package to form a system in package (SIP) configuration. In some examples at least a portion of the components of the computing system 1000 can be integrated into a multi-chip module (MCM), which can be interconnected with other multi-chip modules into a modular computing system.

It will be appreciated that the computing system 1000 shown herein is illustrative and that variations and modifications are possible. The connection topology, including the number and arrangement of bridges, the number of processor(s) 1002, and the number of parallel processor(s) 1012, may be modified as desired. For instance, system memory 1004 can be connected to the processor(s) 1002 directly rather than through a bridge, while other devices communicate with system memory 1004 via the memory hub 1005 and the processor(s) 1002. In other alternative topologies, the parallel processor(s) 1012 are connected to the I/O hub 1007 or directly to one of the one or more processor(s) 1002, rather than to the memory hub 1005. In other examples, the I/O hub 1007 and memory hub 1005 may be integrated into a single chip. It is also possible that two or more sets of processor(s) 1002 are attached via multiple sockets, which can couple with two or more instances of the parallel processor(s) 1012.

Some of the particular components shown herein are optional and may not be included in all implementations of the computing system 1000. For example, any number of add-in cards or peripherals may be supported, or some components may be eliminated. Furthermore, some architectures may use different terminology for components similar to those illustrated in FIG. 10. For example, the memory hub 1005 may be referred to as a Northbridge in some architectures, while the I/O hub 1007 may be referred to as a Southbridge.

Illustrative examples of the technologies disclosed herein are provided below. An embodiment of the technologies may include any one or more, and any compatible combination of, the examples described below.

Example 1 is an apparatus that includes first, second, and subsequent PI cells. The first PI cell includes first PI cell inputs and first PI cell outputs. The second PI cell includes second PI cell inputs and second PI cell outputs, the first PI cell outputs coupled to the second PI cell inputs. The subsequent PI cells are coupled together and include a subsequent PI cell input that is coupled to the second PI cell output.

Example 2 includes the subject matter of example 1, and wherein the first PI cell includes: (i) a first inverter including a first inverter input, a first inverter output, a first inverter high supply reference node, and a first inverter low supply reference node, (ii) a second inverter including a second inverter input, a second inverter output, a second inverter high supply reference node coupled to the first inverter high supply reference node, and a second inverter low supply reference node coupled to the first inverter low supply reference node, (iii) a first transistor coupled between the first transistor high supply reference node and a high supply node and including a first transistor gate coupled to the first inverter input, and (iv) a second transistor coupled between the first transistor low supply reference node and a low supply node and including a first transistor gate coupled to the first inverter input.

Example 3 includes the subject matter of any of examples 1-2, and wherein the first PI cell includes an error correction PI cell stage.

Example 4 includes the subject matter of any of examples 1-3, and wherein the first PI cell includes a first stage of switchable 2:1 PI cells and a second subsequent stage including the error correction PI cell stage.

Example 5 includes the subject matter of any of examples 1-4, and comprising adjustable capacitors coupled to the first PI cell outputs.

Example 6 includes the subject matter of any of examples 1-5, and wherein the second PI cell includes a second error correction PI cell stage.

Example 7 includes the subject matter of any of examples 1-6, and wherein the second PI cell includes a second-PI-cell first stage of switchable 2:1 PI cells and a second-PI-cell second subsequent stage including the error correction PI cell stage.

Example 8 includes the subject matter of any of examples 1-7, and wherein the first, second and subsequent PI cells are single bit coded 2:2 PI cells.

Example 9 includes the subject matter of any of examples 1-8, and wherein the first and second PI cells are single bit coded 2:2 PI cells and at least one of the subsequent PI cells are a 2:2 multi-bit flash PI cell.

Example 10 includes the subject matter of any of examples 1-9, and wherein the first, second and subsequent PI cells are single bit coded 2:2 PI cells.

Example 11 includes the subject matter of any of examples 1-10, and wherein the second and subsequent single bit coded 2:2 PI cells include first and second 2:1 PI cells, the second and subsequent 2:2 PI cells including a transition state where both the first and second 2:1 PI cells are in a midpoint interpolation mode.

Example 12 includes the subject matter of any of examples 1-11, and comprising a control circuit to control at least some of the second and subsequent single bit coded 2:2 PI cells to be in the transition state between transitioning a bit of the first 2:2 PI cell.

Example 13 is an apparatus that includes a multiplexer and four clock channel circuits. The first clock channel circuit includes a first plurality of at least three sequentially coupled first phase interpolator (PI) cells. The second clock channel circuit includes a second plurality of at least three sequentially coupled second PI cells. The third clock channel circuit includes a third plurality of at least three sequentially coupled third PI cells. The fourth clock channel circuit includes a fourth plurality of at least three sequentially coupled fourth PI cells. The one or more multiplexer circuits are coupled to the first, second, third and fourth clock channel circuits to provide each with a different quarter-phase clock input.

Example 14 includes the subject matter of example 13, and wherein one or more of the first, second, third and fourth PI cells include 2:1 PI cells with common tail transistors.

Example 15 includes the subject matter of any of examples 13-14, and wherein one or more of the first, second, third and fourth PI cells include an error correction PI cell stage.

Example 16 includes the subject matter of any of examples 13-15, and wherein the error correction PI cell stage is coupled to more than one of the first, second, third and fourth clock channel circuits.

Example 17 includes the subject matter of any of examples 13-16, and comprising adjustable capacitors coupled to one or more outputs of initial stages of the sequentially coupled first, second, third and fourth PI cells.

Example 18 includes the subject matter of any of examples 13-17, and wherein the first, second, third and fourth sequentially coupled PI cells include single bit coded 2:2 PI cells.

Example 19 includes the subject matter of any of examples 13-18, and wherein first and second PI cells of the sequentially coupled first, second, third and fourth PI cells are single bit coded 2:2 PI cells and at least one subsequent PI cell of the sequentially coupled first, second, third and fourth PI cells is a 2:2 multi-bit flash PI cell.

Example 20 is an apparatus that includes first and second dies. The second die is configured to be coupled to the first die through an interconnect with a receiver circuit. The receiver circuit includes first, second and subsequent PI cells. The first PI cell includes first PI cell inputs and first PI cell outputs. The second PI cell includes second PI cell inputs and second PI cell outputs with the first PI cell outputs coupled to the second PI cell inputs. The coupled together subsequent PI cells include a subsequent PI cell input that is coupled to the second PI cell output.

Example 21 includes the subject matter of example 20, and wherein the first PI cell includes: (i) a first inverter including a first inverter input, a first inverter output, a first inverter high supply reference node, and a first inverter low supply reference node, (ii) a second inverter including a second inverter input, a second inverter output, a second inverter high supply reference node coupled to the first inverter high supply reference node, and a second inverter low supply reference node coupled to the first inverter low supply reference node, (iii) a first transistor coupled between the first transistor high supply reference node and a high supply node and including a first transistor gate coupled to the first inverter input, and (iv) a second transistor coupled between the first transistor low supply reference node and a low supply node and including a first transistor gate coupled to the first inverter input.

Example 22 includes the subject matter of any of examples 20-21, and wherein the first PI cell includes an error correction PI cell stage.

Example 23 includes the subject matter of any of examples 20-22, and wherein the first PI cell includes a first stage of switchable 2:1 PI cells and a second subsequent stage including the error correction PI cell stage.

Example 24 includes the subject matter of any of examples 20-23, and comprising adjustable capacitors coupled to the first PI cell outputs.

Example 25 includes the subject matter of any of examples 20-24, and wherein the second PI cell includes a second error correction PI cell stage.

Example 26 includes the subject matter of any of examples 20-25, and wherein the second PI cell includes a second-PI-cell first stage of switchable 2:1 PI cells and a second-PI-cell second subsequent stage including the error correction PI cell stage.

Example 27 includes the subject matter of any of examples 20-26, and wherein the first, second and subsequent PI cells are single bit coded 2:2 PI cells.

Example 28 includes the subject matter of any of examples 20-27, and wherein the first and second PI cells are single bit coded 2:2 PI cells and at least one of the subsequent PI cells are a 2:2 multi-bit flash PI cell.

Example 29 includes the subject matter of any of examples 20-28, and wherein the first, second and subsequent PI cells are single bit coded 2:2 PI cells.

Example 30 includes the subject matter of any of examples 20-29, and wherein the second and subsequent single bit coded 2:2 PI cells include first and second 2:1 PI cells, the second and subsequent 2:2 PI cells including a transition state where both the first and second 2:1 PI cells are in a midpoint interpolation mode.

Example 31 includes the subject matter of any of examples 20-30, and comprising a control circuit to control at least some of the second and subsequent single bit coded 2:2 PI cells to be in the transition state between transitioning a bit of the first 2:2 PI cell.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

For purposes of the embodiments, unless expressly described differently, the transistors in various circuits and logic blocks described herein may be implemented with any suitable transistor type such as field effect transistors (FETs) or bipolar type transistors. FET transistor types may include but are not limited to metal oxide semiconductor (MOS) type FETs such as tri-gate, FinFET, and gate all around (GAA) FET transistors, as well as tunneling FET (TFET) transistors, ferroelectric FET (FeFET) transistors.

In the drawings of the embodiments, signals are represented with lines. Some lines may appear different from others, for example, thicker or hatched, to distinguish from other depicted signals for ease of understanding. Along these lines, some signal lines may have arrows at one or more ends, to indicate a primary direction of information flow. However, such indications are not intended to be limiting. Rather, lines are used in connection with one or more exemplary embodiments in a given figure to facilitate easier understanding of concepts embodied in block, circuit, and/or flow diagrams. Any represented signal, as dictated by design needs or preferences, may actually comprise one or more signals that may travel in either direction and may be implemented with any suitable type of signal scheme, e.g., analog, digital, wired, wireless, upon the platform within which the present disclosure is to be implemented.

As defined herein, the term “computer readable storage medium” means a storage medium that contains or stores program code for use by or in connection with an instruction execution system, apparatus, or device. As defined herein, a “computer readable storage medium” is not a transitory, propagating signal per se. A computer readable storage medium may be, but is not limited to, an electronic storage device, a magnetic storage device, an optical storage device, an electromagnetic storage device, a semiconductor storage device, or any suitable combination of the foregoing. Memory elements, as described herein, are examples of a computer readable storage medium.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, and so forth. It should be appreciated that a logical processor, on the other hand, is a processing abstraction associated with a core, for example when one or more SMT cores are being used such that multiple logical processors may be associated with a given core, for example, in the context of core thread assignment.

It should be appreciated that a processor or processor system may be implemented in various different manners. For example, they may be implemented on a single die, multiple dies (dielets, chiplets), one or more dies in a common package, or one or more dies in multiple packages. Along these lines, some of these blocks may be located separately on different dies or together on two or more different dies.

While the flow diagrams in the figures show a particular order of operations performed by certain embodiments of the invention, it should be understood that such order is exemplary (e.g., alternative embodiments may perform the operations in a different order, combine certain operations, overlap certain operations, etc.).

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. An apparatus, comprising:
a first phase interpolator (PI) cell including first PI cell inputs and first PI cell outputs;
a second PI cell including second PI cell inputs and second PI cell outputs, the first PI cell outputs coupled to the second PI cell inputs; and
one or more coupled together subsequent PI cells including a subsequent PI cell input that is coupled to the second PI cell output.

2. The apparatus of claim 1, wherein the first PI cell includes:
a first inverter including a first inverter input, a first inverter output, a first inverter high supply reference node, and a first inverter low supply reference node,
a second inverter including a second inverter input, a second inverter output, a second inverter high supply reference node coupled to the first inverter high supply reference node, and a second inverter low supply reference node coupled to the first inverter low supply reference node,
a first transistor coupled between the first transistor high supply reference node and a high supply node and including a first-transistor gate coupled to the first inverter input; and
a second transistor coupled between the first transistor low supply reference node and a low supply node and including a second-transistor gate coupled to the first inverter input.

3. The apparatus of claim 1, wherein the first PI cell includes an error correction PI cell stage.

4. The apparatus of claim 3, wherein the first PI cell includes a first stage of switchable 2:1 PI cells and a second subsequent stage including the error correction PI cell stage.

5. The apparatus of claim 1, comprising adjustable capacitors coupled to the first PI cell outputs.

6. The apparatus of claim 1, wherein the first, second and subsequent PI cells are single bit coded 2:2 PI cells.

7. The apparatus of claim 1, wherein the first and second PI cells are single bit coded 2:2 PI cells and at least one of the subsequent PI cells are a 2:2 multi-bit flash PI cell.

8. The apparatus of claim 1, wherein the first, second and subsequent PI cells are single bit coded 2:2 PI cells.

9. The apparatus of claim 8, wherein the second and subsequent single bit coded 2:2 PI cells include first and second 2:1 PI cells, the second and subsequent 2:2 PI cells including a transition state where both the first and second 2:1 PI cells are in a midpoint interpolation mode.

10. The apparatus of claim 9, comprising a control circuit to control at least some of the second and subsequent single bit coded 2:2 PI cells to be in the transition state between transitioning a bit of the first 2:2 PI cell.

11. An apparatus, comprising:
a first clock channel circuit including a first plurality of at least three sequentially coupled first phase interpolator (PI) cells;
a second clock channel circuit including a second plurality of at least three sequentially coupled second PI cells;
a third clock channel circuit including a third plurality of at least three sequentially coupled third PI cells;
a fourth clock channel circuit including a fourth plurality of at least three sequentially coupled fourth PI cells; and
one or more multiplexer circuits coupled to the first, second, third and fourth clock channel circuits to provide each with a different quarter-phase clock input.

12. The apparatus of claim 11, wherein one or more of the first, second, third and fourth PI cells include 2:1 PI cells with common tail transistors.

13. The apparatus of claim 11, wherein one or more of the first, second, third and fourth PI cells include an error correction PI cell stage.

14. The apparatus of claim 13, wherein the error correction PI cell stage is coupled to more than one of the first, second, third and fourth clock channel circuits.

15. The apparatus of claim 11, comprising adjustable capacitors coupled to one or more outputs of initial stages of the sequentially coupled first, second, third and fourth PI cells.

16. The apparatus of claim 11, wherein first and second PI cells of the sequentially coupled first, second, third and fourth PI cells are single bit coded 2:2 PI cells and at least one subsequent PI cell of the sequentially coupled first, second, third and fourth PI cells is a 2:2 multi-bit flash PI cell.

17. A system, comprising:
a processor package including a first die and a second die coupled to the first die through an interconnect with a receiver circuit including:
a first phase interpolator (PI) cell including first PI cell inputs and first PI cell outputs;
a second PI cell including second PI cell inputs and second PI cell outputs, the first PI cell outputs coupled to the second PI cell inputs; and
one or more coupled together subsequent PI cells including a subsequent PI cell input that is coupled to the second PI cell output; and
a memory device coupled to the processor package.

18. The apparatus of claim 17, wherein the first PI cell includes an error correction PI cell stage.

19. The apparatus of claim 18, wherein the first PI cell includes a first stage of switchable 2:1 PI cells and a second subsequent stage including the error correction PI cell stage.

20. The apparatus of claim 17, wherein the first, second and subsequent PI cells are single bit coded 2:2 PI cells.
